(19) United States
(12) Patent Application Publication
(10) Pub. No.: US 2025/0351394 A1
(43) Pub. Date: Nov. 13, 2025

(54) SEMICONDUCTOR DEVICE AND METHOD FOR MANUFACTURING THE SAME

(71) Applicant: Murata Manufacturing Co., Ltd., Kyoto-fu (JP)

(72) Inventors: Mitsuhiro NAKAMURA, Nagaokakyo-shi (JP); Kenji SASAKI, Nagaokakyo-shi (JP)

(73) Assignee: Murata Manufacturing Co., Ltd., Kyoto-fu (JP)

(21) Appl. No.: 19/190,017

(22) Filed: Apr. 25, 2025

(30) Foreign Application Priority Data
May 9, 2024 (JP) 2024-076562

(51) Int. Cl. H10D 10/80; H10D 10/01; H10D 62/10

(52) U.S. Cl. CPC H10D 10/821; H10D 10/021; H10D 62/117

(57) ABSTRACT

In a semiconductor device, on a surface of an emitter layer including a compound semiconductor of a first conductor type, facing in a first direction, a base layer including a compound semiconductor of a second conductor type opposite from the first conductor type and subjected to heterojunction to the emitter layer is disposed. At least one collector mesa including a compound semiconductor of the first conductor type is disposed on a surface of the base layer facing in the first direction. An emitter electrode is disposed on a surface of the emitter layer facing in a second direction opposite to the first direction. A base electrode continuously surrounding the collector mesa in plan view is disposed on the surface of the base layer facing in the first direction. A collector electrode is disposed on a surface of the collector mesa facing in the first direction.

### CROSS-REFERENCE TO RELATED APPLICATION

This application claims benefit of priority to Japanese Patent Application No. 2024-076562, filed May 9, 2024, the entire content of which is incorporated herein by reference.

### BACKGROUND

### Technical Field

The present disclosure relates to a semiconductor device and a method for manufacturing the semiconductor device.

### Background Art

A heterojunction bipolar transistor (HBT) in which a base layer is disposed on a collector layer, and an emitter mesa is disposed on the base layer is known (Japanese Unexamined Patent Application Publication No. 5-243257). Japanese Unexamined Patent Application Publication No. 5-243257 refers to a collector-up structure in which a base layer is disposed on an emitter layer, and a collector mesa is disposed on the base layer.

In an HBT in which a collector layer is disposed on the substrate side, in plan view, base electrodes are disposed on both sides across an emitter mesa, and collector electrodes are disposed on the outer side relative to the base electrodes. In the collector-up structure, base electrodes are disposed on both sides across the collector mesa, and emitter electrodes are disposed on the outer side relative to the base electrodes.

### SUMMARY

In the HBT disclosed in Japanese Unexamined Patent Application Publication No. 5-243257, in plan view, the base electrode is disposed in two directions, opposite to each other, when viewed from the collector mesa, but no base electrode is disposed in two directions orthogonal to the above-described directions. As described above, since there are a direction in which the base electrode is disposed and a direction in which no base electrode is disposed, the in-plane uniformity of a collector current density in the collector mesa is degraded. It is difficult to increase breakdown resistance in such a structure in which the in-plane uniformity of the collector current density is degraded.

Accordingly, the present disclosure provides a semiconductor device capable of enhancing the in-plane uniformity of the current density of a collector current in a collector mesa, and a method for manufacturing the semiconductor device.

According to one aspect of the present disclosure, there is provided a semiconductor device including an emitter layer including a compound semiconductor of a first conductor type; a base layer disposed on a surface of the emitter layer facing in a first direction and including a compound semiconductor of a second conductor type opposite from the first conductor type, the base layer being subjected to heterojunction to the emitter layer; at least one collector mesa disposed on a surface of the base layer facing in the first direction and including a compound semiconductor of the first conductor type; an emitter electrode disposed on a surface of the emitter layer facing in a second direction opposite to the first direction; a base electrode disposed on the surface of the base layer facing in the first direction and continuously surrounding the collector mesa in plan view; and a collector electrode disposed on a surface of the collector mesa facing in the first direction.

According to another aspect of the present disclosure, there is provided a method for manufacturing a semiconductor device. The method includes forming a release layer on a surface of a temporary substrate facing in a first direction; forming an emitter layer including a compound semiconductor of a first conductor type on a surface of the release layer facing in the first direction; forming a base layer including a compound semiconductor of a second conductor type opposite from the first conductor type, on a surface of the emitter layer facing in the first direction; forming at least one collector mesa including a compound semiconductor of the first conductor type on a surface of the base layer facing in the first direction; forming a base electrode on the surface of the base layer facing in the first direction; forming a collector electrode on a surface of the collector mesa facing in the first direction; releasing the emitter layer from the temporary substrate by etching and removing the release layer; forming an emitter electrode on a surface of the emitter layer facing in a second direction opposite to the first direction; and joining the emitter electrode to a support substrate.

Since the base electrode continuously surrounds the collector mesa in plan view, the symmetry of the shape constituted by the base electrode and the collector mesa is enhanced. As a result, the in-plane uniformity of the current density of a collector current in the collector mesa is enhanced.

### BRIEF DESCRIPTION OF THE DRAWINGS

FIG. 1 is a plan view of a semiconductor device according to a first embodiment;

FIG. 2 is a sectional view taken along dot-and-dash line 2-2 in FIG. 1;

FIGS. 3A, 3B, and 3C are sectional views of the semiconductor device according to the first embodiment in the middle of manufacturing;

FIG. 4A is a plan view of the semiconductor device according to the first embodiment in the middle of manufacturing, and FIG. 4B is a sectional view taken along dot-and-dash line 4B-4B in FIG. 4A;

FIG. 5A is a plan view of the semiconductor device according to the first embodiment in the middle of manufacturing, and FIG. 5B is a sectional view taken along dot-and-dash line 5B-5B in FIG. 5A;

FIG. 6 is a plan view of a semiconductor device according to a modification example of the first embodiment;

FIG. 7 is a plan view of a semiconductor device according to another modification example of the first embodiment;

FIG. 8 is a plan view of a semiconductor device according to a second embodiment;

FIGS. 9A and 9B are plan views of a first layer 30B1 and a second layer 30B2 of a base electrode 30B of the semiconductor device according to the second embodiment, respectively;

FIG. 10 is a sectional view taken along dot-and-dash line 10-10 in FIG. 8;

FIG. 11 is a plan view of a semiconductor device according to a modification example of the second embodiment;

FIGS. 12A and 12B are plan views of a first layer 30B1 and a second layer 30B2 of the semiconductor device according to the modification example of the second embodiment, respectively;

FIG. 13 is a plan view of a semiconductor device according to a third embodiment;

FIG. 14 is a sectional view of a semiconductor device according to a fourth embodiment;

FIGS. 15A and 15B are sectional views of the semiconductor device according to the fourth embodiment in the middle of manufacturing; and

FIG. 16 is a sectional view of a semiconductor device according to a fifth embodiment.

### DETAILED DESCRIPTION

### First Embodiment

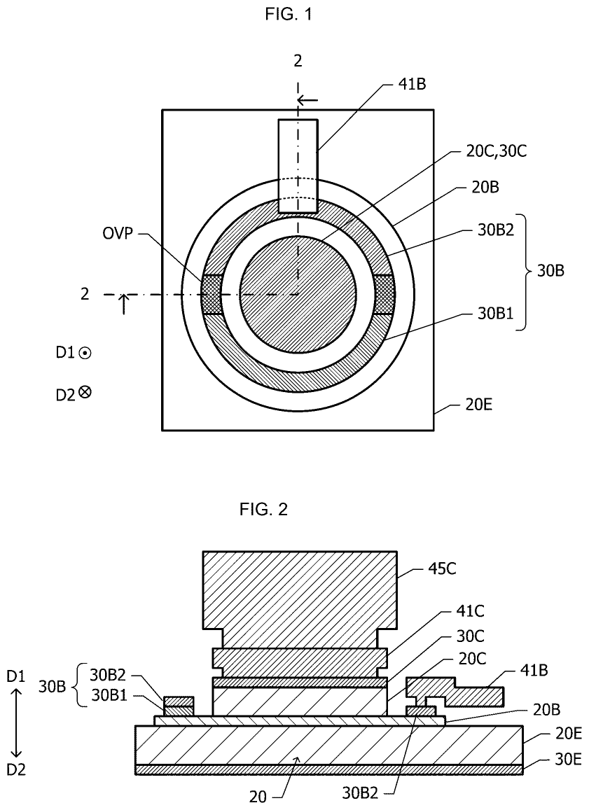

A semiconductor device according to a first embodiment will be described with reference to FIGS. 1 to 5B.

FIG. 1 is a plan view of the semiconductor device according to the first embodiment, and FIG. 2 is a sectional view taken along dot-and-dash line 2-2 in FIG. 1. Note that illustration of an interlayer insulating film is omitted in FIG. 2.

A base layer 20B is disposed on a partial region of a surface of an emitter layer 20E facing in a first direction D1 (the surface facing frontward in FIG. 1, the surface facing upward in FIG. 2). A collector mesa 20C is disposed on a surface of the base layer 20B facing in the first direction D1. The shapes of the base layer 20B and the collector mesa 20C are each circular in plan view. In the present specification, surfaces of parts facing in the first direction D1 are each sometimes referred to as an upper surface.

The emitter layer 20E includes a compound semiconductor of a first conductor type, and the base layer 20B includes a compound semiconductor of a second conductor type opposite from the first conductor type. Here, in the “first conductor type” and the “second conductor type”, one refers to an n-type conductivity type, and the other refers to a p-type conductivity type. The collector mesa 20C includes a compound semiconductor of the first conductor type. The emitter layer 20E and the base layer 20B form a heterojunction. For example, the emitter layer 20E is made of n-type InGaP, the base layer 20B is made of p-type GaAs, and the collector mesa 20C is made of n-type GaAs. The emitter layer 20E, the base layer 20B, and the collector mesa 20C constitute a heterojunction bipolar transistor (HBT) 20.

Note that an etch stop layer may be disposed on the entire upper surface of the base layer 20B, and the collector mesa 20C may be disposed on the etch stop layer. The etch stop layer is made of a semiconductor material different in etch resistance from the collector mesa 20C. For example, when n-type GaAs is used for the collector mesa 20C, for example, n-type InGaP or n-type AlAs is used for the etch stop layer.

A collector electrode 30C is disposed on the entire upper surface of the collector mesa 20C. In FIG. 1, the collector electrode 30C is hatched with oblique lines rising to the right. The collector electrode 30C is in ohmic contact with the collector mesa 20C. The collector electrode 30C and the collector mesa 20C are patterned by using, for example, a self-alignment process.

A base electrode 30B is disposed on a region, in the surface of the base layer 20B facing in the first direction D1, on which the collector mesa 20C is not disposed. The base electrode 30B is in ohmic contact with the base layer 20B. When the etch stop layer is disposed on the upper surface of the base layer 20B, the base electrode 30B passes through the etch stop layer in a thickness direction and reaches the base layer 20B.

The base electrode 30B continuously surrounds the collector mesa 20C in plan view. That is, the collector mesa 20C is disposed inside a closed pattern constituted by the base electrode 30B. Such a “closed pattern” here refers to a pattern in which, when moving in one direction along the pattern, a point returns to the original position. The interval between the outer peripheral line of the collector mesa 20C and the inner peripheral line of the base electrode 30B is substantially constant in a peripheral direction. The collector mesa 20C is processed by using, for example, dry etching.

The base electrode 30B includes a first layer 30B1 and a second layer 30B2. In FIG. 1, the first layer 30B1 is hatched with oblique lines going down to the right, and the second layer 30B2 is hatched with oblique lines rising to the right. A portion of the first layer 30B1 overlaps a portion of the second layer 30B2, and each of the first layer 30B1 and the second layer 30B2 includes no closed pattern in plan view. The first layer 30B1 and the second layer 30B2 as a whole continuously surround the collector mesa 20C in plan view.

For example, each of the first layer 30B1 and the second layer 30B2 has a circular arc shape along the common circumference in plan view, and end portions of both overlap each other. That is, the sum of the central angle of the circular arc along which the first layer 30B1 extends and the central angle of the circular arc along which the second layer 30B2 extends is larger than 360 degrees. In an overlap region OVP, the first layer 30B1 is disposed closer to the base layer 20B than the second layer 30B2.

An extreme end of a first-layer base wire 41B overlaps a portion of the upper surface of the base electrode 30B, and the base wire 41B extends outside the base layer 20B in plan view. A first-layer collector wire 41C is disposed on the upper surface of the collector electrode 30C. A collector bump 45C for external circuit connection is disposed on the upper surface of the collector wire 41C. In FIG. 1, illustration of the collector wire 41C and the collector bump 45C is omitted.

An emitter electrode 30E is disposed on a surface of the emitter layer 20E facing in a second direction D2 opposite to the first direction D1. The emitter electrode 30E is in ohmic contact with the emitter layer 20E. In the present specification, surfaces of parts facing in the second direction D2 are each sometimes referred to as a “lower surface”.

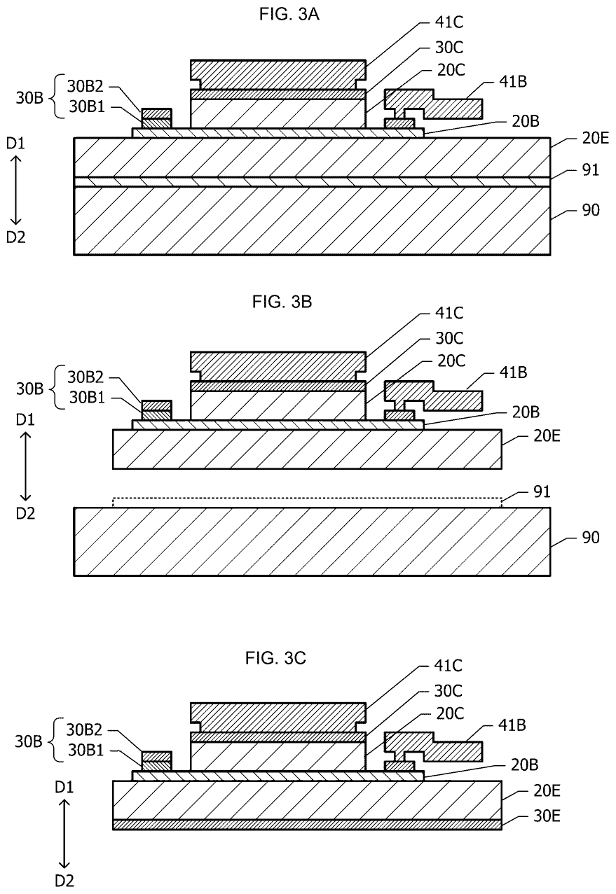

Next, a method for manufacturing the semiconductor device according to the first embodiment will be described with reference to FIGS. 3A, 3B, and 3C. FIGS. 3A, 3B, and 3C are sectional views of the semiconductor device according to the first embodiment in the middle of manufacturing.

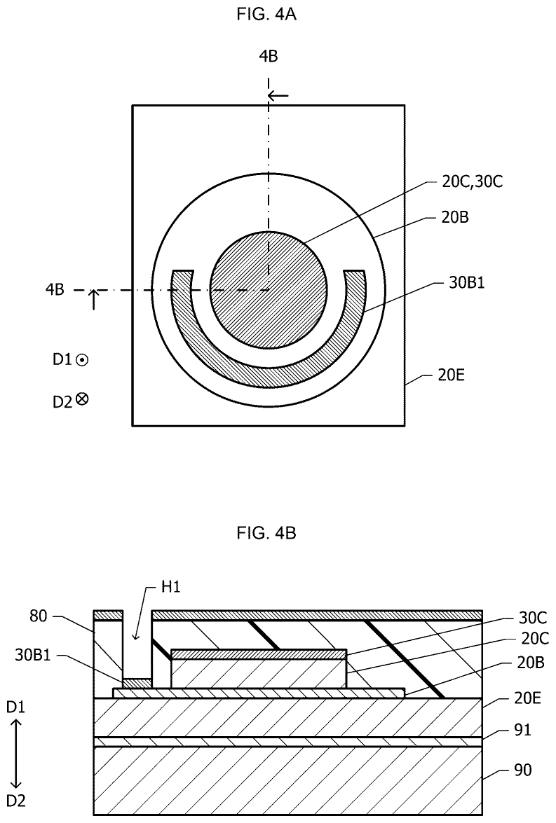

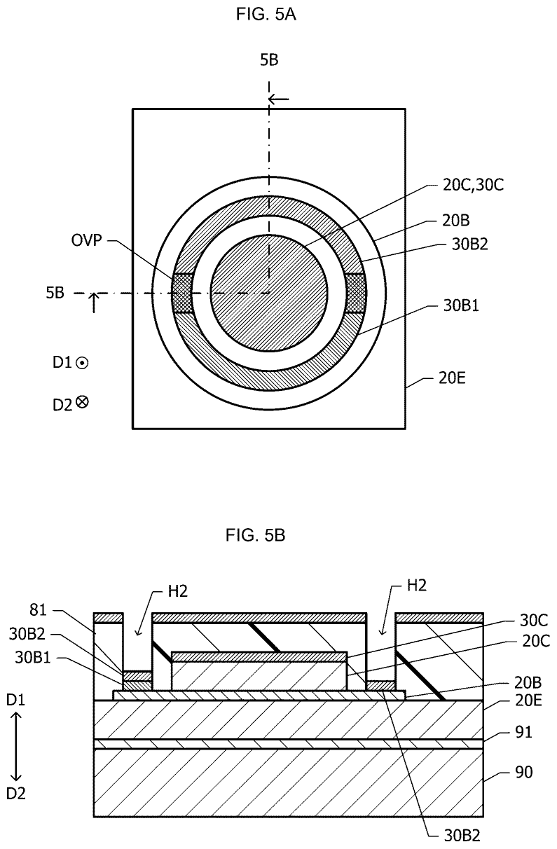

As FIG. 3A illustrates, a release layer 91 is epitaxially grown on a temporary substrate 90 made of a compound semiconductor. Further, the emitter layer 20E is epitaxially grown on the release layer 91. An element structure including the base layer 20B, the collector mesa 20C, the base electrode 30B, the collector electrode 30C, the first-layer base wire 41B, and the first-layer collector wire 41C is formed on the upper surface of the emitter layer 20E. The above constituents can be formed by typical semiconductor processes. The procedure for forming the base electrode 30B will be described in detail later with reference to FIGS. 4A to 5B.

In this stage, the emitter layer 20E is disposed on the entire upper surface of the temporary substrate 90, and element structures (chips) of multiple semiconductor devices are disposed on the upper surface of the emitter layer 20E. FIG. 3A illustrates only one chip part. Note that one chip also includes, for example, multiple heterojunction bipolar transistors 20 and other passive elements (not illustrated).

As FIG. 3B illustrates, the emitter layer 20E and the release layer 91 are patterned to be divided on a chip basis. In this stage, multiple chips are supported by the temporary substrate 90 that is common thereto. A protective tape (not illustrated) is stuck on the upper surfaces of the multiple chips. The multiple chips are coupled to one another by the protective tape.

The release layer 91 is selectively etched and removed, and the chips each including the emitter layer 20E and the like are thus released from the temporary substrate 90. The multiple chips are in a state of being coupled to one another by the protective tape.

As FIG. 3C illustrates, the emitter electrode 30E is formed on the lower surface of the emitter layer 20E. In one example, after the emitter electrode 30E is formed, each of the chips is released from the protective tape, and the emitter electrode 30E is joined to, for example, a support substrate. After the chip is joined to the support substrate, the collector bump 45C (FIG. 2) and the like are formed.

Next, the procedure for forming the base electrode 30B will be described with reference to FIGS. 4A to 5B. FIGS. 4A and 5A are plan views of the semiconductor device in the middle of manufacturing, and FIGS. 4B and 5B are a sectional view taken along dot-and-dash line 4B-4B in FIG. 4A and a sectional view taken along dot-and-dash line 5B-5B in FIG. 5A, respectively. The base electrode 30B is formed by using a lift-off process.

As FIG. 4B illustrates, after the collector electrode 30C and the collector mesa 20C are formed, a resist film 80 for covering the emitter layer 20E, the base layer 20B, the collector mesa 20C, and the collector electrode 30C is formed. Subsequently, a cavity H1 matching a planar pattern of the first layer 30B1 of the base electrode 30B is formed in the resist film 80. A conductor film is formed on the upper surface of the base layer 20B exposed at a bottom plane of the cavity H1 and on the upper surface of the resist film 80. The resist film 80, with the conductor film covering the upper surface of the resist film 80, is removed. As a result of this, the first layer 30B1 of the base electrode 30B remains on the upper surface of the base layer 20B. As FIG. 4A illustrates, the first layer 30B1 includes no closed pattern in plan view.

As FIG. 5B illustrates, after the first layer 30B1 of the base electrode 30B is formed, a resist film 81 for covering the emitter layer 20E, the base layer 20B, the collector mesa 20C, the collector electrode 30C, and the first layer 30B1 is formed. Subsequently, a cavity H2 matching a planar pattern of the second layer 30B2 of the base electrode 30B is formed in the resist film 81. Inside the cavity H2, in the overlap regions OVP (FIG. 5A), the first layer 30B1 is exposed, and, in the other region, the base layer 20B is exposed.

A conductor film is formed on the upper surfaces of the base layer 20B and the first layer 30B1 exposed at a bottom plane of the cavity H2 and on the upper surface of the resist film 81. The resist film 81, with the conductor film covering the upper surface of the resist film 81, is removed. As a result of this, the second layer 30B2 of the base electrode 30B remains on the upper surface of the base layer 20B and in the overlap regions OVP. As FIG. 5A illustrates, the second layer 30B2 includes no closed pattern in plan view. Note that the first layer 30B1 and the second layer 30B2 as a whole constitute a closed pattern.

Next, advantageous effects of the first embodiment will be described.

In the semiconductor device according to the first embodiment, since the collector mesa 20C has a circular shape in plan view, and the base electrode 30B (FIG. 1) continuously surrounds the collector mesa 20C, the base electrode 30B is disposed so as to face the entire outer peripheral line of the collector mesa 20C. That is, the base electrode 30B is disposed in every direction when viewed from the collector mesa 20C, and the symmetry of the shapes of the collector mesa 20C and the base electrode 30B in plan view is enhanced. Thus, the in-plane uniformity of the current density of a collector current in the collector mesa 20C is enhanced. The collector current hardly concentrates at a specific spot, and an advantageous effect of improving the breakdown resistance of the heterojunction bipolar transistor 20 can thus be obtained.

In addition, since the emitter electrode 30E made of a metal material is disposed on the entire lower surface of the emitter layer 20E, the resistance of a current path from an external circuit to the emitter layer 20E is suppressed from increasing.

Moreover, in the first embodiment, the base electrode 30B is disposed so as to face the entire outer peripheral line of the collector mesa 20C. In contrast, in a configuration in which base electrodes are disposed on both sides of a collector mesa, there is a portion of the outer periphery of the collector mesa that no base electrode faces. Thus, in the semiconductor device according to the first embodiment, base resistance can be reduced compared with the configuration in which the base electrodes are disposed on both sides of the collector mesa.

Moreover, in the first embodiment, the first layer 30B1 and the second layer 30B2 of the base electrode 30B are formed by different lift-off processes, and the conductor pattern to be formed in the first lift-off process includes no closed pattern. Usually, when a conductor pattern formed by using a lift-off process includes a closed pattern, yield tends to be reduced. In the first embodiment, the base electrode 30B including a closed pattern is formed by the second lift-off process, thereby suppressing reduction in yield.

In addition, in the heterojunction bipolar transistor 20 according to the first embodiment, parasitic capacitance Cbc between the base and the collector is generated in a region in which the collector mesa 20C (FIG. 1) is disposed. Since no base-collector junction interface exists in the region in which the base electrode 30B is disposed, a region occupied by the base electrode 30B does not become a factor in increasing the parasitic capacitance Cbc between the base and the collector. Thus, by forming the base electrode 30B in a closed ring shape, the parasitic capacitance Cbc between the base and the collector is prevented from increasing even when the area of the region occupied by the base electrode 30B is increased.

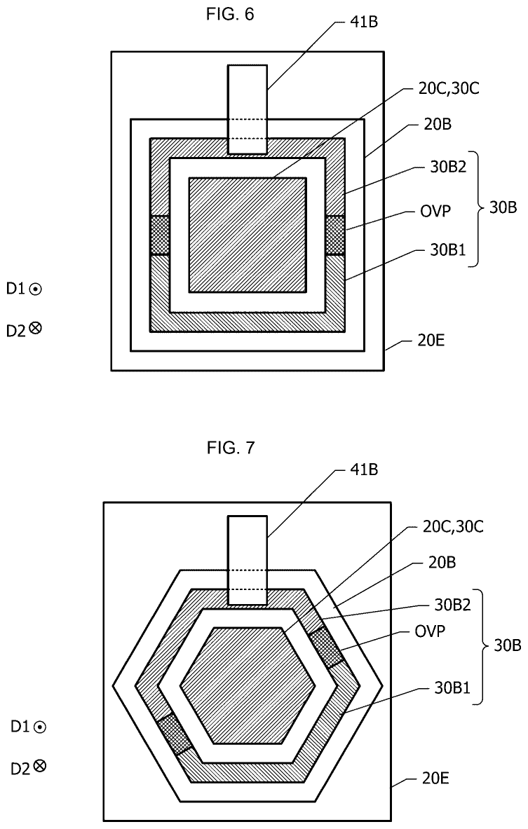

Next, semiconductor devices according to modification examples of the first embodiment will be described with reference to FIGS. 6 and 7. FIGS. 6 and 7 are plan views of the semiconductor devices according to the modification examples of the first embodiment. In the first embodiment (FIG. 1), the pattern of the base electrode 30B is a closed pattern along the circumference in plan view, but other closed patterns may be possible.

In the modification example illustrated in FIG. 6, the pattern of a base electrode 30B is a closed pattern along the outer periphery of a square in plan view. In the example illustrated in FIG. 6, overlap regions OVP are disposed substantially at midpoints of a pair of sides of the square facing each other but may be disposed at other spots. In the modification example illustrated in FIG. 7, the pattern of a base electrode 30B is a closed pattern along the outer periphery of a regular hexagon in plan view. In the example illustrated in FIG. 7, overlap regions OVP are disposed substantially at midpoints of a pair of sides of the regular hexagon facing each other but may be disposed at other spots. The shape of a collector mesa 20C in plan view is reflective of the pattern of the base electrode 30B. For example, the shape of the collector mesa 20C is a square in the modification example illustrated in FIG. 6, and the shape of the collector mesa 20C is a regular hexagon in the modification example illustrated in FIG. 7.

Next, advantageous effects of the first embodiment and the modification examples thereof will be described.

When the collector mesa 20C is shaped in a circle as in the first embodiment (FIG. 1), the shapes of the collector mesa 20C and the base electrode 30B in plan view have the highest degree of symmetry. Moreover, the length of a current path from the outer periphery of the collector mesa 20C to the base electrode 30B is substantially constant over the entire outer periphery of the collector mesa 20C. Thus, there is provided an advantage in enhancing the uniformity of the current density of the collector current in the plane of the collector mesa 20C.

On the other hand, in the modification examples illustrated in FIGS. 6 and 7, as described in a second embodiment later, structures each constituted by the base electrode 30B and the collector mesa 20C can be laid all over a two-dimensional plane. Thus, in a configuration in which multiple collector mesas 20C are disposed, the modification examples illustrated in FIGS. 6 and 7 are better in space usage efficiency.

Although FIG. 6 illustrates the example in which the base electrode 30B extends along the outer periphery of a square, and FIG. 7 illustrates the example in which the base electrode 30B extends along the outer periphery of a regular hexagon, the “square” and the “regular hexagon” are not necessarily strictly a square or a regular hexagon geometrically. A shape into which a square or a regular hexagon is slightly deformed may be possible. For example, deformation from a square or a regular hexagon is allowed in a range where the sufficient in-plane uniformity of the current density of the collector current in the collector mesa 20C is maintained.

Multiple heterojunction bipolar transistors 20 illustrated in each of FIGS. 1, 6, and 7 may be connected in parallel to increase output. In this case, to suppress thermal runaway, a base ballast resistor is preferably connected to each of the heterojunction bipolar transistors 20.

### Second Embodiment

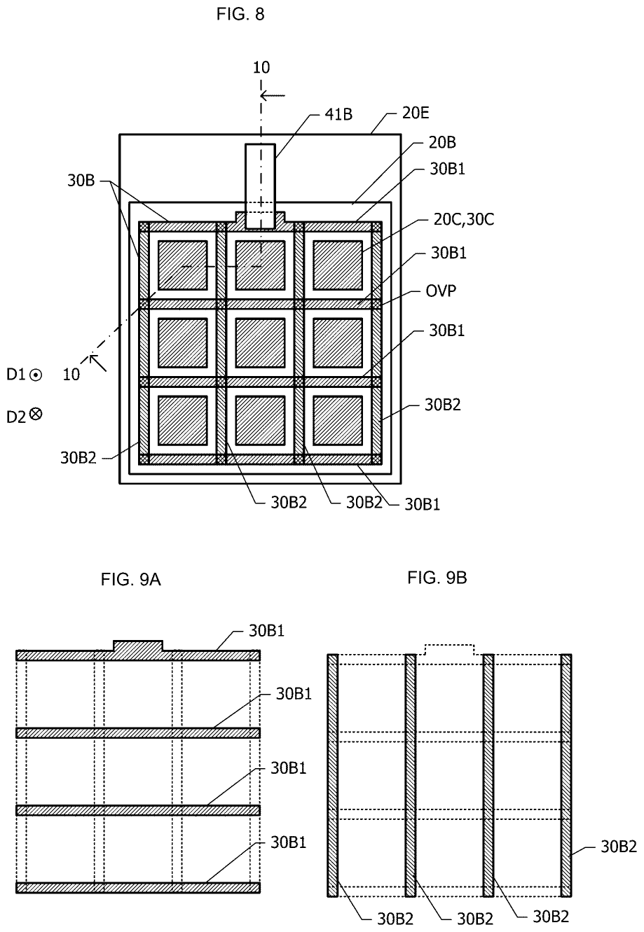

Next, a semiconductor device according to the second embodiment will be described with reference to FIGS. 8 to 10. Hereinafter, the description of a configuration common to the semiconductor devices according to the first embodiment and the modification examples thereof described with reference to FIGS. 1 to 7 is omitted.

FIG. 8 is a plan view of the semiconductor device according to the second embodiment. There is only one collector mesa 20C in the first embodiment (FIG. 1), but multiple collector mesas 20C are disposed discretely in the second embodiment. A base electrode 30B continuously surrounds each of the multiple collector mesas 20C. In the base electrode 30B, a portion disposed between two adjacent collector mesas 20C is shared as a portion surrounding the collector mesas 20C on both sides.

More specifically, the base electrode 30B has a square lattice shape in which vertical and horizontal lines are orthogonal to each other. The collector mesas 20C are disposed in respective multiple divisions (cells) divided by the vertical lines and the horizontal lines of the lattice shape. In plan view, the outer peripheral line of each of the multiple collector mesas 20C faces an edge of the base electrode 30B with a gap therebetween and has a shape along the edge of the base electrode 30B. Each of the multiple divisions divided by the lattice pattern in which the vertical lines and the horizontal lines are orthogonal to one another has a square shape, and the collector mesa 20C thus also has a square shape in plan view.

The base electrode 30B includes a first layer 30B1 and a second layer 30B2 as with the case of the first embodiment. In FIG. 8, each first layer 30B1 is hatched with oblique lines rising to the right, and each second layer 30B2 is hatched with oblique lines going down to the right. Further, a collector electrode 30C is hatched with oblique lines rising to the right.

FIGS. 9A and 9B are plan views of the first layer 30B1 and the second layer 30B2 of the base electrode 30B, respectively. The first layer 30B1 (FIG. 9A) and the second layer 30B2 (FIG. 9B) have patterns corresponding to the horizontal line and the vertical line of the square lattice shape, respectively. The first layer 30B1 and the second layer 30B2 overlap each other at a lattice point (an overlap region OVP) at which the horizontal line and the vertical line intersect each other. Neither the first layer 30B1 nor the second layer 30B2 includes a closed pattern.

In plan view, a portion of the outermost periphery of the lattice-shaped base electrode 30B is widened, and a first-layer base wire 41B (FIG. 8) is connected to the widened spot. In plan view, the base wire 41B extends outside a base layer 20B without intersecting any collector mesa 20C and any collector electrode 30C.

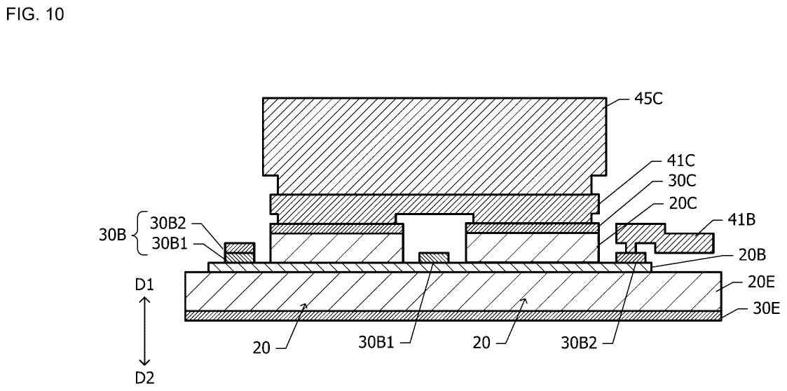

FIG. 10 is a sectional view taken along dot-and-dash line 10-10 in FIG. 8. The multiple collector mesas 20C are disposed on the upper surface of the base layer 20B. In the section illustrated in FIG. 10, two collector mesas 20C are appearing. The collector electrode 30C is disposed on the upper surface of each of the collector mesas 20C. A first-layer collector wire 41C electrically connects the multiple collector electrodes 30C to each other. A collector bump 45C is disposed on the upper surface of the collector wire 41C.

The first-layer base wire 41B is electrically connected to the portion of the outermost periphery of the base electrode 30B. The base wire 41B intersects the edge of the base layer 20B and extends outside the base layer 20B in plan view.

Next, advantageous effects of the second embodiment will be described.

In the second embodiment, as with the first embodiment, the base electrode 30B is also disposed so as to face the entire outer peripheral line of the collector mesa 20C, and the in-plane uniformity of the current density of the collector current in the collector mesa 20C is thus enhanced in each of the collector mesas 20C. Moreover, neither the first layer 30B1 nor the second layer 30B2 of the base electrode 30B includes a closed pattern in plan view, thereby suppressing reduction in yield in a forming step of the base electrode 30B.

In addition, the multiple collector mesas 20C are distributed discretely, thereby being able to make the base electrode 30B electrically continuous in the same layer. The first-layer base wire 41B does not intersect any of the multiple collector electrodes 30C in plan view, and the collector wire 41C disposed in the same conductor layer as the conductor layer including the first-layer base wire 41B can thereby electrically connect all the collector electrodes 30C to one another. Moreover, the collector bump 45C disposed on the upper surface of the collector wire 41C can be electrically connected to the collector mesa 20C by the shortest path. For example, in plan view, the collector wire 41C and the collector bump 45C can be disposed in a region in which the collector wire 41C and the collector bump 45C overlap the collector mesa 20C and the collector electrode 30C.

In addition, the base electrode 30B (FIG. 8) can be constituted by vertical and horizontal lines. A diagonal line does not fit a grid serving as a guide for pattern arrangement when a pattern is CAD engineered, and a difficulty in laying out thereby arises. In the second embodiment, the pattern of the base electrode 30B can be designed only with vertical and horizontal lines, thereby being able to obtain an advantageous effect of facilitating the laying out of the base electrode 30B.

Although the base electrode 30B has a lattice shape in which the vertical lines and the horizontal lines are orthogonal to one another in the second embodiment, the vertical lines and the horizontal lines are not necessarily strictly orthogonal to one another geometrically and may be slightly deviate from such an orthogonal relationship under the condition that the sufficient in-plane uniformity of the current density of the collector current in the collector mesa 20C can be maintained. Similarly, the division divided by the base electrode 30B may be slightly deformed from the square.

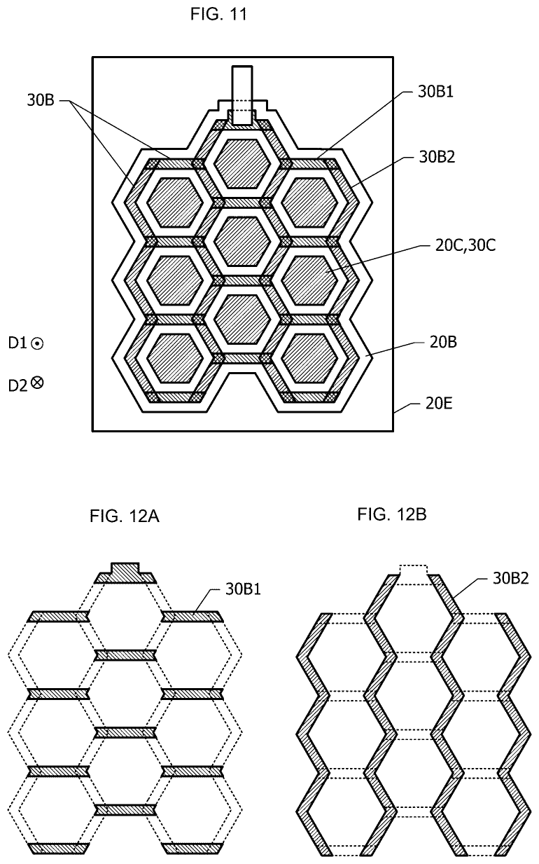

Next, a semiconductor device according to a modification example of the second embodiment will be described with reference to FIGS. 11, 12A, and 12B.

FIG. 11 is a plan view of the semiconductor device according to the modification example of the second embodiment. Although the base electrode 30B has a square lattice shape in which the vertical lines and the horizontal lines are orthogonal to one another in the second embodiment (FIG. 8), a base electrode 30B has a honeycomb shape in the present modification example. Multiple regular hexagonal divisions (cells) divided by the base electrode 30B are formed. A collector mesa 20C and a collector electrode 30C are disposed in each of the multiple divisions. In plan view, the shapes of the collector mesa 20C and the collector electrode 30C are reflective of the shape of the division and are thus each a regular hexagon. The base electrode 30B includes a first layer 30B1 and a second layer 30B2 as with the second embodiment.

FIGS. 12A and 12B are plan views of the first layer 30B1 and the second layer 30B2, respectively. As FIG. 12A illustrates, the first layers 30B1 are constituted by multiple portions of the base electrode 30B extending along sides of the regular hexagon that are parallel to one direction (a lateral direction in FIGS. 11 and 12A). As FIG. 12B illustrates, the second layers 30B2 are constituted by multiple portions extending along, in the six sides of the regular hexagon, sides other than the sides along which the first layers 30B1 extend. That is, the second layers 30B2 extend in a zigzag manner in a direction orthogonal to a longitudinal direction of each of the first layers 30B1. End portions of each of the first layers 30B1 overlap corner portions of the corresponding zigzag second layers 30B2.

As in the present modification example, the base electrode 30B may have a honeycomb shape. In the present modification example, each of the first layer 30B1 and the second layer 30B2 includes no closed pattern in plan view.

Note that each of the multiple divisions divided by the base electrode 30B does not necessarily have a regular hexagonal shape and may have a convex hexagonal shape into which a regular hexagon is slightly deformed, under the condition that the sufficient in-plane uniformity of the current density of the collector current in the collector mesa 20C can be maintained.

### Third Embodiment

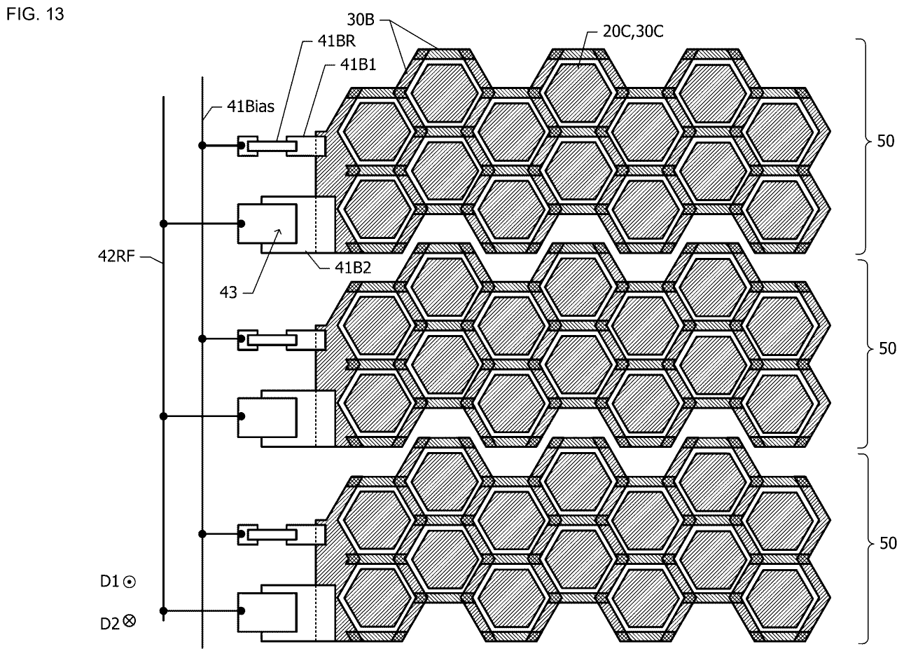

Next, a semiconductor device according to a third embodiment will be described with reference to FIG. 13. Hereinafter, the description of a configuration common to the semiconductor device according to the modification example of the second embodiment described with reference to FIGS. 11, 12A, and 12B is omitted.

FIG. 13 is a plan view of the semiconductor device according to the third embodiment. The semiconductor device according to the third embodiment includes multiple units 50. Each of the multiple units 50 has a configuration similar to that of the semiconductor device according to the modification example of the second embodiment (FIG. 11). Note that the arrangement of multiple collector mesas 20C of each of the units 50 differs from the arrangement of the collector mesas 20C of the semiconductor device according to the modification example of the second embodiment illustrated in FIG. 11. A base electrode 30B is provided for each of the units 50, and the base electrodes 30B are not directly connected to one another between the units 50.

First-layer base wires 41B1 and 41B2 connected to the base electrode 30B are disposed in each of the units 50. Multiple base wires 41B are each connected to a common bias wire 41Bias with a base ballast resistance element 41BR therebetween. The other base wires 41B2 are each connected to a common signal input wire 42RF with an input capacitor 43 therebetween.

Next, advantageous effects of the third embodiment will be described.

When the temperature of any one of the units 50 rises, a current concentrates in the unit 50 and raises the temperature of the unit 50 more and more, which causes thermal runaway. In the third embodiment, the base ballast resistance element 41BR is disposed for each of the units 50, thereby being able to suppress current concentration in the unit 50 in which a collector current has relatively increased. Thus, an advantageous effect of hardly causing thermal runaway can be obtained.

Next, a semiconductor device according to a modification example of the third embodiment will be described.

The base electrode 30B of each of the units 50 has a honeycomb shape in the third embodiment but may have a square lattice shape in which vertical and horizontal lines are orthogonal to each other as with the base electrode 30B of the semiconductor device according to the second embodiment illustrated in FIG. 8.

### Fourth Embodiment

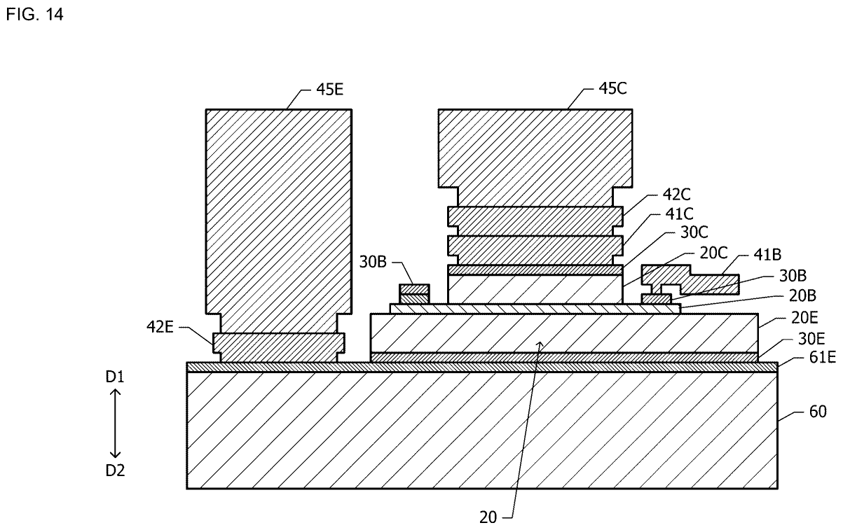

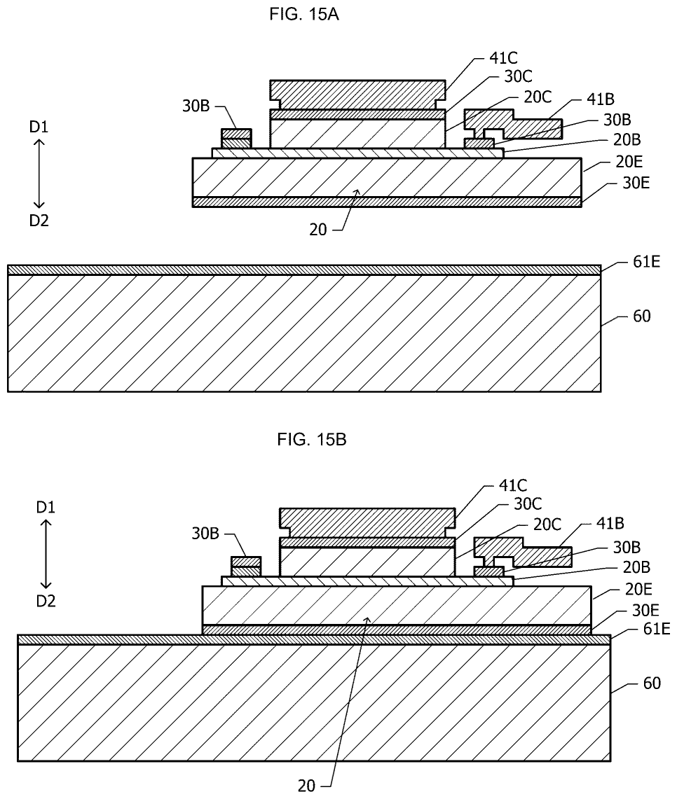

Next, a semiconductor device according to a fourth embodiment will be described with reference to FIGS. 14, 15A, and 15B. Hereinafter, the description of a configuration common to the semiconductor devices according to the first embodiment, the second embodiment, and the third embodiment described with reference to FIGS. 1 to 13 is omitted.

FIG. 14 is a sectional view of the semiconductor device according to the fourth embodiment. The semiconductor device according to the fourth embodiment includes a support substrate 60 having a mechanically sufficient support force. A substrate having a thermal conductivity higher than the thermal conductivity of an emitter layer 20E serves as the support substrate 60. For example, a substrate including silicon (such as a silicon substrate) serves as the support substrate 60.

The semiconductor device according to the fourth embodiment includes an element structure identical to the element structure of the semiconductor device according to the first embodiment (FIG. 2) from the emitter electrode 30E to the first-layer collector wire 41C and the first-layer base wire 41B. Note that the semiconductor device according to the fourth embodiment may include an element structure identical to the element structure of, for example, the semiconductor device according to the second embodiment (FIGS. 8 and 10), the semiconductor device according to the modification example of the second embodiment (FIG. 11), or the semiconductor device according to the third embodiment (FIG. 13).

An emitter wire 61E is disposed on a surface of the support substrate 60 facing in the first direction D1. A surface of an emitter electrode 30E equivalent to the surface, of the emitter electrode 30E of the semiconductor device according to the first embodiment, facing in the second direction D2 is joined to the emitter wire 61E, and the emitter electrode 30E is electrically connected to the emitter wire 61E. In plan view, the support substrate 60 is larger than the emitter layer 20E, and the emitter wire 61E extends outside the emitter electrode 30E.

An emitter bump 45E for external circuit connection is disposed on the side ahead in the first direction D1 when viewed from the emitter wire 61E. In plan view, the emitter bump 45E is disposed at a position where the emitter bump 45E overlaps the emitter wire 61E and does not overlap the emitter electrode 30E and the emitter layer 20E. An emitter wire 42E is disposed between the emitter bump 45E and the emitter wire 61E, and the emitter bump 45E is electrically connected to the emitter wire 61E with the emitter wire 42E therebetween.

A second-layer collector wire 42C is disposed on the upper surface of a first-layer collector wire 41C, and a collector bump 45C is disposed on the upper surface of the second-layer collector wire 42C. The collector bump 45C is electrically connected to the collector electrode 30C with the collector wires 42C and 41C therebetween. The collector wire 42C and the emitter wire 42E are disposed in the same wiring layer.

The semiconductor device according to the fourth embodiment is mounted on a module substrate or the like with the emitter bump 45E and the collector bump 45C facing the module substrate or the like.

Next, a method for manufacturing the semiconductor device according to the fourth embodiment will be described with reference to FIGS. 15A and 15B. FIGS. 15A and 15B are sectional views of the semiconductor device according to the fourth embodiment in the middle of manufacturing.

As FIG. 15A illustrates, an element structure from the emitter electrode 30E on the lower surface of the emitter layer 20E to the first-layer collector wire 41C and a first-layer base wire 41B is prepared. A method for preparing the element structure is identical to the method for manufacturing the semiconductor device according to the first embodiment described with reference to FIGS. 3A to 5B. The emitter wire 61E is formed on a surface on one side of the support substrate 60.

As FIG. 15B illustrates, the emitter electrode 30E is caused to face the emitter wire 61E, and both are joined. This joining is achieved by, for example, van der Waals bonding or hydrogen bonding. Alternatively, the joining may be achieved by, for example, electrostatic force, covalent bonding, or eutectic alloy bonding.

After the emitter electrode 30E is joined to the emitter wire 61E, as FIG. 14 illustrates, the second-layer emitter wire 42E and the second-layer collector wire 42C are formed on surfaces, of the element structure and the emitter wire 61E, facing in the first direction, and the emitter bump 45E and the collector bump 45C are further formed. The above constituents are formed by using a typical multilayer-wiring-layer forming process.

Next, advantageous effects of the fourth embodiment will be described.

In the fourth embodiment, the support substrate 60 serves as a substrate for mechanically supporting the element structure including an HBT 20 and further functions as a heat-dissipating path from the HBT 20. Usually, the thermal conductivities of the compound semiconductors constituting the emitter layer 20E, a base layer 20B, and a collector mesa 20C of the HBT 20 are lower than the thermal conductivity of the support substrate 60 including silicon. By joining the element structure including the HBT 20 to the support substrate 60 whose thermal conductivity is relatively high, good heat dissipation from the HBT 20 can be ensured.

Moreover, a current path from the emitter bump 45E to the emitter layer 20E is constituted by the emitter wires 42E and 61E and the emitter electrode 30E that are each made of a metal material, and the current path includes no semiconductor material. Thus, the resistance from the emitter layer 20E to an external circuit to which the emitter layer 20E is connected can be suppressed from increasing.

### Fifth Embodiment

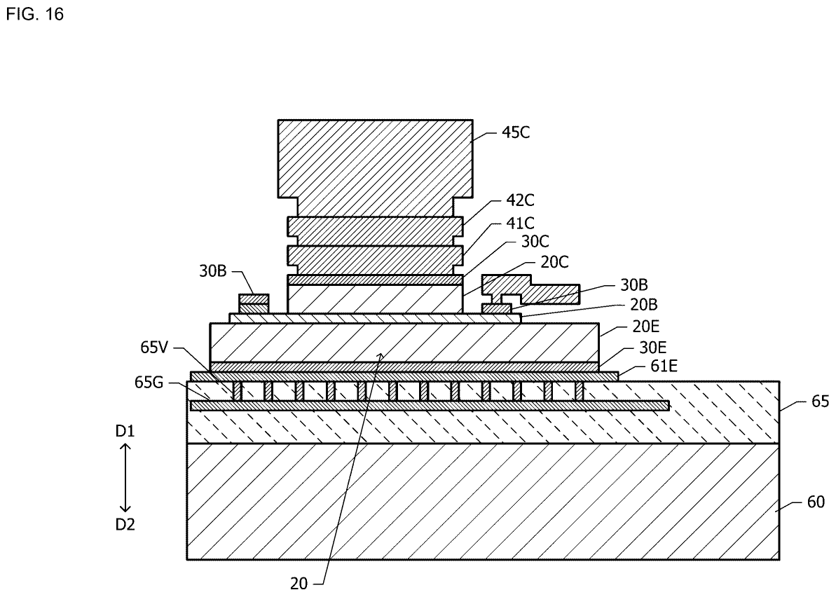

Next, a semiconductor device according to a fifth embodiment will be described with reference to FIG. 16. Hereinafter, the description of a configuration common to the semiconductor device according to the fourth embodiment described with reference to FIGS. 14, 15A, and 15B is omitted.

FIG. 16 is a sectional view of the semiconductor device according to the fifth embodiment. In the semiconductor device according to the fourth embodiment (FIG. 14), the emitter bump 45E is disposed on the side ahead in the first direction D1 when viewed from the emitter wire 61E. In contrast, in the fifth embodiment, no emitter bump is disposed on the side ahead in the first direction D1 when viewed from an emitter wire 61E.

A multilayer wiring layer 65 is formed on a surface of a support substrate 60 facing in the first direction D1. The emitter wire 61E is disposed on a surface of the multilayer wiring layer 65 facing in the first direction D1. An emitter layer 20E of an HBT 20 is electrically connected to a ground conductor 65G in the multilayer wiring layer 65 with an emitter electrode 30E, the emitter wire 61E, and multiple vias 65V in the multilayer wiring layer 65 therebetween.

Next, advantageous effects of the fifth embodiment will be described.

In the fifth embodiment, as with the fourth embodiment, the support substrate 60 also functions as a heat-dissipating path from the HBT 20. Moreover, the emitter of the HBT 20 can be connected to the ground conductor 65G formed over the support substrate 60, without interposing a bump for external circuit connection therebetween.

The emitter electrode 30E made of a metal material is provided on the entire lower surface of the emitter layer 20E, and the entire lower surface of the emitter electrode 30E is connected to the emitter wire 61E. Further, the emitter wire 61E is connected to the ground conductor 65G with the multiple vias 65V in the multilayer wiring layer 65 therebetween. Thus, the resistance of a current path from the emitter layer 20E to the ground conductor 65G can be reduced.

Note that each of the above-described embodiments is an example, and configurations presented in the different embodiments may be partially replaced or combined. Similar actions and effects exhibited by similar configurations of the multiple embodiments are not referred to, one by one, in each of the embodiments. Moreover, the present disclosure is not limited to the above-described embodiments. For example, it will be obvious to those skilled in the art that, for example, various modifications, improvements, and combinations are possible.

The following disclosure is disclosed based on the above embodiments described in the present specification.
<1> A semiconductor device including an emitter layer including a compound semiconductor of a first conductor type; a base layer disposed on a surface of the emitter layer facing in a first direction and including a compound semiconductor of a second conductor type opposite from the first conductor type, the base layer being subjected to heterojunction to the emitter layer; at least one collector mesa disposed on a surface of the base layer facing in the first direction and including a compound semiconductor of the first conductor type; an emitter electrode disposed on a surface of the emitter layer facing in a second direction opposite to the first direction; a base electrode disposed on the surface of the base layer facing in the first direction and continuously surrounding the collector mesa in plan view; and a collector electrode disposed on a surface of the collector mesa facing in the first direction.
<2> The semiconductor device according to the item <1>, in which the collector mesa has a circular shape, a square shape, or a regular hexagonal shape in plan view.
<3> The semiconductor device according to the item <1>, in which the at least one collector mesa comprises multiple collector mesas, the multiple collector mesas are disposed discretely, the base electrode continuously surrounds each of the collector mesas, and a portion of the base electrode disposed between two adjacent collector mesas of the multiple collector mesas is shared between the two collector mesas.
<4> The semiconductor device according to the item <3>, in which a portion of the base electrode has, in plan view, a lattice shape in which vertical and horizontal lines are orthogonal to each other, and the multiple collector mesas are disposed in respective multiple cells surrounded by the vertical and horizontal lines of the lattice shape.
<5> The semiconductor device according to the item <3>, in which a portion of the base electrode has a honeycomb shape in plan view, and the multiple collector mesas are disposed in respective multiple cells of the honeycomb shape.
<6> The semiconductor device according to the item <4> or <5>, in which, in plan view, an outer peripheral line of each of the multiple collector mesas faces an edge of the base electrode with a gap therebetween and has a shape along the edge of the base electrode.
<7> The semiconductor device according to any one of the items <1> to <6>, in which the base electrode includes two layers including a first layer and a second layer, a portion of the first layer overlaps a portion of the second layer, each of the first layer and the second layer includes no closed pattern, and the first layer and the second layer as a whole continuously surround the collector mesa.
<8> The semiconductor device according to any one of the items <1> to <7>, further including a collector bump for external circuit connection, in which the collector bump is disposed on a side ahead in the first direction when viewed from the collector electrode and disposed at a position where the collector bump partially overlaps the collector electrode in plan view.
<9> The semiconductor device according to any one of the items <1> to <8>, further including a support substrate disposed on a surface of the emitter electrode facing in the second direction, in which a thermal conductivity of the support substrate is higher than a thermal conductivity of the emitter layer.
<10> A method for manufacturing a semiconductor device. The method includes forming a release layer on a surface of a temporary substrate facing in a first direction; forming an emitter layer including a compound semiconductor of a first conductor type on a surface of the release layer facing in the first direction; forming a base layer including a compound semiconductor of a second conductor type opposite from the first conductor type, on a surface of the emitter layer facing in the first direction; forming at least one collector mesa including a compound semiconductor of the first conductor type on a surface of the base layer facing in the first direction; forming a base electrode on the surface of the base layer facing in the first direction; forming a collector electrode on a surface of the collector mesa facing in the first direction; releasing the emitter layer from the temporary substrate by etching and removing the release layer; forming an emitter electrode on a surface of the emitter layer facing in a second direction opposite to the first direction; and joining the emitter electrode to a support substrate.
<11> The method for manufacturing a semiconductor device according to the item <10>, in which the base electrode includes two layers including a first layer and a second layer, each of the first layer and the second layer includes no closed pattern, the first layer and the second layer as a whole continuously surround the collector mesa, and, in the forming the base electrode, the first layer is formed by a lift-off process, and the second layer is then formed by another lift-off process.

What is claimed is:

1. A semiconductor device comprising:
an emitter layer including a compound semiconductor of a first conductor type;
a base layer on a surface of the emitter layer facing in a first direction and including a compound semiconductor of a second conductor type opposite from the first conductor type, the base layer being subjected to heterojunction to the emitter layer;
at least one collector mesa on a surface of the base layer facing in the first direction and including a compound semiconductor of the first conductor type;
an emitter electrode on a surface of the emitter layer facing in a second direction opposite to the first direction;
a base electrode on the surface of the base layer facing in the first direction and continuously surrounding the collector mesa in plan view; and
a collector electrode on a surface of the collector mesa facing in the first direction.

2. The semiconductor device according to claim 1, wherein
the collector mesa has a circular shape, a square shape, or a regular hexagonal shape in plan view.

3. The semiconductor device according to claim 1, wherein
the at least one collector mesa comprises multiple collector mesas, the multiple collector mesas are disposed discretely,
the base electrode continuously surrounds each of the collector mesas, and a portion of the base electrode between two adjacent collector mesas of the multiple collector mesas is shared between the two collector mesas.

4. The semiconductor device according to claim 3, wherein
a portion of the base electrode has, in plan view, a lattice shape in which vertical and horizontal lines are orthogonal to each other, and
the multiple collector mesas are in respective multiple cells surrounded by the vertical and horizontal lines of the lattice shape.

5. The semiconductor device according to claim 3, wherein
a portion of the base electrode has a honeycomb shape in plan view, and
the multiple collector mesas are in respective multiple cells of the honeycomb shape.

6. The semiconductor device according to claim 4, wherein,
in plan view, an outer peripheral line of each of the multiple collector mesas faces an edge of the base electrode with a gap therebetween and has a shape along the edge of the base electrode.

7. The semiconductor device according to claim 1, wherein
the base electrode includes two layers including a first layer and a second layer, a portion of the first layer overlaps a portion of the second layer, each of the first layer and the second layer includes no closed pattern, and the first layer and the second layer as a whole continuously surround the collector mesa.

8. The semiconductor device according to claim 1, further comprising:
a collector bump for external circuit connection, wherein
the collector bump is on a side ahead in the first direction when viewed from the collector electrode and at a position where the collector bump partially overlaps the collector electrode in plan view.

9. The semiconductor device according to claim 1, further comprising:
a support substrate on a surface of the emitter electrode facing in the second direction, wherein
a thermal conductivity of the support substrate is higher than a thermal conductivity of the emitter layer.

10. The semiconductor device according to claim 5, wherein,
in plan view, an outer peripheral line of each of the multiple collector mesas faces an edge of the base electrode with a gap therebetween and has a shape along the edge of the base electrode.

11. The semiconductor device according to claim 2, wherein
the base electrode includes two layers including a first layer and a second layer, a portion of the first layer overlaps a portion of the second layer, each of the first layer and the second layer includes no closed pattern, and the first layer and the second layer as a whole continuously surround the collector mesa.

12. The semiconductor device according to claim 3, wherein
the base electrode includes two layers including a first layer and a second layer, a portion of the first layer overlaps a portion of the second layer, each of the first layer and the second layer includes no closed pattern, and the first layer and the second layer as a whole continuously surround the collector mesa.

13. The semiconductor device according to claim 4, wherein
the base electrode includes two layers including a first layer and a second layer, a portion of the first layer overlaps a portion of the second layer, each of the first layer and the second layer includes no closed pattern, and the first layer and the second layer as a whole continuously surround the collector mesa.

14. The semiconductor device according to claim 2, further comprising:
a collector bump for external circuit connection, wherein
the collector bump is on a side ahead in the first direction when viewed from the collector electrode and at a position where the collector bump partially overlaps the collector electrode in plan view.

15. The semiconductor device according to claim 3, further comprising:
a collector bump for external circuit connection, wherein
the collector bump is on a side ahead in the first direction when viewed from the collector electrode and at a position where the collector bump partially overlaps the collector electrode in plan view.

16. The semiconductor device according to claim 4, further comprising:
a collector bump for external circuit connection, wherein
the collector bump is on a side ahead in the first direction when viewed from the collector electrode and at a position where the collector bump partially overlaps the collector electrode in plan view.

17. The semiconductor device according to claim 2, further comprising:
a support substrate on a surface of the emitter electrode facing in the second direction, wherein
a thermal conductivity of the support substrate is higher than a thermal conductivity of the emitter layer.

18. The semiconductor device according to claim 3, further comprising:
a support substrate on a surface of the emitter electrode facing in the second direction, wherein
a thermal conductivity of the support substrate is higher than a thermal conductivity of the emitter layer.

19. A method for manufacturing a semiconductor device, the method comprising:
forming a release layer on a surface of a temporary substrate facing in a first direction;
forming an emitter layer including a compound semiconductor of a first conductor type on a surface of the release layer facing in the first direction;
forming a base layer including a compound semiconductor of a second conductor type opposite from the first conductor type, on a surface of the emitter layer facing in the first direction;
forming at least one collector mesa including a compound semiconductor of the first conductor type on a surface of the base layer facing in the first direction;
forming a base electrode on the surface of the base layer facing in the first direction;
forming a collector electrode on a surface of the collector mesa facing in the first direction;
releasing the emitter layer from the temporary substrate by etching and removing the release layer;
forming an emitter electrode on a surface of the emitter layer facing in a second direction opposite to the first direction; and
joining the emitter electrode to a support substrate.

20. The method for manufacturing a semiconductor device according to claim 19, wherein
the base electrode includes two layers including a first layer and a second layer, each of the first layer and the second layer includes no closed pattern, the first layer and the second layer as a whole continuously surround the collector mesa, and,
in the forming the base electrode, the first layer is formed by a lift-off process, and the second layer is then formed by another lift-off process.
